(19) United States
(12) Patent Application Publication
(10) Pub. No.: US 2023/0122292 A1
(43) Pub. Date: Apr. 20, 2023

(54) OPTOELECTRONIC PACKAGE AND METHOD FOR MANUFACTURING THE SAME

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW); Jung Jui KANG, Kaohsiung (TW)

(73) Assignee: Advanced Semiconductor Engineering, Inc., Kaohsiung (TW)

(21) Appl. No.: 17/506,465

(22) Filed: Oct. 20, 2021

(51) Int. Cl. H01L 25/16; H01L 23/00; H01L 23/538

(52) U.S. Cl. CPC H01L 25/167; H01L 24/08; H01L 23/5386; H01L 23/5389; H01L 2224/16145; H01L 2224/16227

(57) ABSTRACT

An optoelectronic package includes an input/output (I/O) component, a photonic component, and an electronic component configured to modulate optical signals in the photonic component. The I/O component is electrically connected to the photonic component via the electronic component.

### 1. TECHNICAL FIELD

The present disclosure relates generally to optoelectronic packages and methods for manufacturing optoelectronic packages.

### 2. DESCRIPTION OF THE RELATED ART

The demand for network information has increased year by year due to implementations for cloud services, Internet of Things (IoT), 5G applications, etc. Such applications require high speed data transmission. While operating at higher and higher speeds and frequencies, traditional cable transmission experiences signal integrity issues due to the high impedance generated by capacitance and inductance of traditional cables. Signal integrity issues cause power loss and limit distance of transmission that can be achieved by traditional cables. In recent years, optical communication is often used in place of traditional cable transmission. In optical communication, optical fibers are used instead of electrically conductive wire among devices.

### SUMMARY

In some arrangements, an optoelectronic package includes an input/output (I/O) component, a photonic component, and an electronic component configured to modulate optical signals in the photonic component. The I/O component is electrically connected to the photonic component via the electronic component.

In some arrangements, an optoelectronic package includes a carrier, a processing component disposed at a first side of the carrier, and an I/O component disposed at a second side of the carrier. The second side of the carrier is opposite to the first side of the carrier.

In some arrangements, an optoelectronic package includes a carrier, an electronic component embedded in the carrier, and an I/O component outside the carrier. The I/O component is electrically connected to the electronic component.

### BRIEF DESCRIPTION OF THE DRAWINGS

Aspects of some arrangements of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a schematic cross-sectional view of an optoelectronic package.

FIG. 2 illustrates a schematic cross-sectional view of an optoelectronic package in accordance with some arrangements of the present disclosure.

FIG. 3 illustrates a schematic top view of an optoelectronic package of FIG. 2 in accordance with some arrangements of the present disclosure.

FIG. 4 illustrates a schematic bottom view of an optoelectronic package of FIG. 2 in accordance with some arrangements of the present disclosure.

FIG. 5 illustrates a schematic cross-sectional view of an optoelectronic package in accordance with some arrangements of the present disclosure.

FIG. 6 illustrates a schematic cross-sectional view of an optoelectronic package in accordance with some arrangements of the present disclosure.

FIG. 7A, FIG. 7B, FIG. 7C, FIG. 7D, FIG. 7E, FIG. 7F, FIG. 7G, FIG. 7H, FIG. 7I, FIG. 7J, FIG. 7K and FIG. 7L illustrate various stages of a method for manufacturing an optoelectronic package in accordance with some arrangements of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

As used herein, the “active side” or “active surface” of a photonic component may refer to a side or a surface along which a waveguide is disposed. The waveguide may be disposed adjacent to the active side or the active surface. The “inactive side” or “inactive surface” of a photonic component may refer to a side or a surface along which no waveguide is disposed.

As used herein, the term “active side” or “active surface” of an electronic component may refer to a side or a surface of an electronic component on which electrical or contact terminals such as contact pads, conductive studs or conductive pillars are disposed, for transmission of electrical signals or power. The “inactive side” or “inactive surface” of an electronic component may refer to a surface of the electronic component on which no contact terminals are disposed.

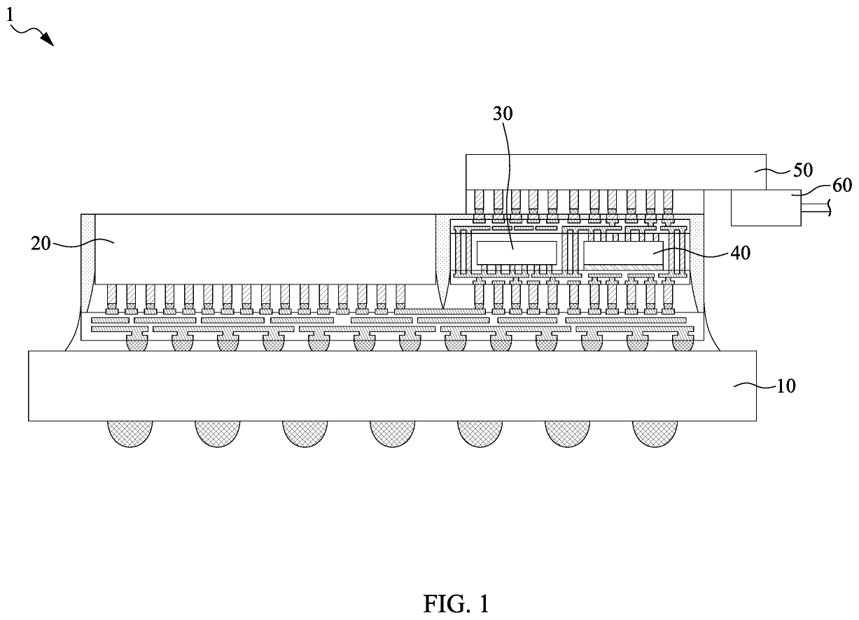

FIG. 1 shows an optoelectronic package 1 including a carrier 10, a processing component 20 (e.g., Application Specific Integrated Circuit (ASIC) die), a input/output (I/O) component 30 (e.g., Serializer-Deserializer (SerDes) die), an electronic component 40 (e.g., electronic die), a photonic component 50 (e.g., photonic die), and an optical component 60 (e.g., fiber array unit (FAU)). The processing component 20, the I/O component 30 and the electronic component 40 are integrated and packaged by a Fan-Out Chip-on-Substrate (FOCoS) technique in two-dimensional (2D) arrangement on the carrier 10. The processing component 20, the I/O component 30, and the electronic component 40 individually occupy separate areas on a top surface of the substrate 10. As shown, an axis parallel to a surface of the carrier 10 facing the processing component 20, the I/O component 30, and the electronic component 40 traverses all of the processing component 20, the I/O component 30, and the electronic component 40. Such 2D, side-by-side arrangement of the processing component 20, the I/O component 30, and the electronic component 40 requires that the carrier 10 have a relatively large dimension (e.g., a relatively large top surface).

The present arrangements relate to optoelectronic packages and methods for manufacturing optoelectronic packages. In some arrangements, the optoelectronic package adopts three-dimensional (3D) arrangement of the processing component 20, the I/O component 30 and/or the electronic component 40. As compared to conventional optoelectronic packages, such 3D arrangement allows the carrier 10 to have a smaller dimension (e.g. a smaller top surface area), and therefore improving miniaturization of the dimensions of optoelectronic packages.

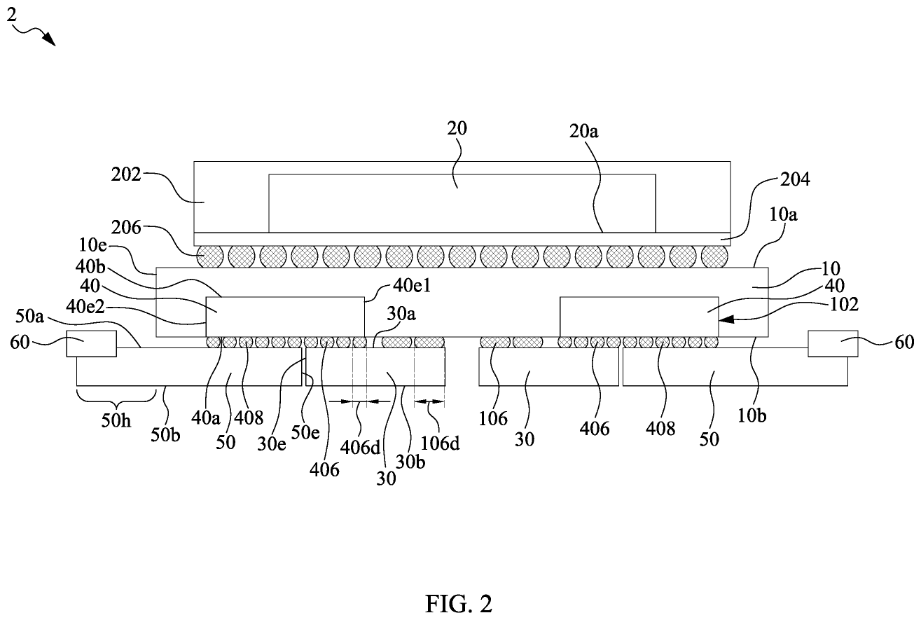

FIG. 2 illustrates a schematic cross-sectional view of an optoelectronic package 2 in accordance with some arrangements of the present disclosure. The optoelectronic package 2 includes one or more of a carrier 10, a processing component 20, an I/O component 30, an electronic component 40, and a photonic component 50.

The carrier 10 has a first surface 10a (e.g., a top surface), a second surface 10b (e.g., a bottom surface) opposite to the first surface 10a, and an edge 10e (also referred to as a lateral surface) connecting the first surface 10a and the second surface 10b. In some arrangements, the carrier 10 includes an electrically conductive structure and a dielectric structure (not shown). The electrically conductive structure may include one or more conductive wiring layers, contact pads (disposed at the top surface 10a and bottom surface 10b of the carrier 10), vias electrically connecting the conductive wiring layers and pads, and so on. In some arrangements, the dielectric structure may include one or more dielectric layers. The one or more dielectric layers and the one or more conductive wiring layers are stacked on one another. The carrier 10 may be or include, a paper-based copper foil laminate, a composite copper foil laminate, a polymer-impregnated glass-fiber-based copper foil laminate, or so on. The carrier 10 may be or include a substrate, such as an organic substrate or a leadframe. The carrier 10 may be or include an interposer, a redistribution layer (RDL), a fan-out substrate, or so on.

The processing component 20 may be or include one or more of a processing die, a logic semiconductor die, a memory die, or so on. In some arrangements, the processing component 20 includes a logic integrated circuits (IC). In some examples, the processing component 20 includes ASIC, and may be referred to as an ASIC die. In some arrangements, the ASIC die can be a switch die used in selecting channels for data communication. In some arrangements, the processing component 20 may be or include a memory die including a SRAM, DRAM, NAND, 3D NAND, Graphics Double Date Rate (GDDR) SDRAM, flash memory, a high bandwidth memory (HBM), or so on. The processing component 20 may be at least partially embedded in or encapsulated by an encapsulant 202. An active surface 20a of the processing component 20 may be exposed from the encapsulant 202. In some examples, the active surface 20a may be substantially coplanar with a surface of the encapsulant 202. In some arrangements, the encapsulant 202 may include an epoxy resin having fillers, a molding compound (e.g., an epoxy molding compound or other molding compound), polyimide, a phenolic compound or material, a material with a silicone dispersed therein, or a combination thereof. The processing component 20 may include a RDL 204 on the active surface 20a of the processing component 20. The RDL 204 may cover and extend across surfaces of the processing component 20 and the encapsulant 202. In some arrangements, the RDL 204 include a dielectric layer and a conductive layer (including a conductive trace and a conductive via) embedded in the dielectric layer. In some arrangements, the RDL 204 may be, but is not limited to, a multi-layered RDL including conductive layers and dielectric layers stacked alternately. In some arrangements, the RDL 204 may include under-bump metal (UBM). The RDL 204 is between the processing component 20 and the carrier 10.

The I/O component 30 has a first surface 30a, a second surface 30b opposite to the first surface 30a, and an edge 30e (also referred to as a lateral surface) connecting the first surface 30a and the second surface 30b. In some arrangements, the first surface 30a of the I/O component 30 is an active surface. In some arrangements, the second surface 30b of the I/O component 30 is an inactive surface. In some arrangements, the I/O component 30 is or includes an electronic die containing an I/O circuits and may be referred to as an I/O die. The I/O component 30 may include a transceiver including a physical-layer circuit or a physical-layer interface portion (normally abbreviated as “PHY”), which connects a physical medium through which data is conveyed to the I/O component 30 from the processing component 20 or from the I/O component 30 to the processing component 20. In some arrangements, the I/O component 30 may be or include a Serializer-Deserializer (SerDes) die. The SerDes die may be used in high speed communications to convert data between serial data and parallel interfaces in order to minimize the number of I/O pins and interconnects.

In some arrangements, the technology node for fabricating the processing component 20 (e.g., 7 nm) may be smaller and more advanced than that for the I/O component 30 (e.g., 28 nm). Therefore, the yield for fabricating the processing component 20 may be relatively low as compared to the I/O component 30. In some arrangements, the processing component 20 may be a die (or chip), and the I/O component 30 may be a plurality of chiplets electrically connected with the processing component 30. The processing component 20 and the I/O component 30 may be manufactured individually and separately such that manufacturing costs can be minimized and manufacturing efficiency can be maximized.

The electronic component 40 may be at least partially embedded in or encapsulated by the carrier 10. The electronic component 40 has a first surface 40a exposed from the substrate 10, a second surface 40b opposite to the first surface 40a, and edges 40e1 and 40e2 (each of which is also referred to as a lateral surface) connecting the first surface 40a and the second surface 40b. In some arrangements, the first surface 40a of the electronic component 40 is an active surface. In some arrangements, the second surface 40b of the electronic component 40 is an inactive surface. In some arrangements, the electronic component 20 may be or include an electronic die, and may also be referred to as a semiconductor die, an electronic semiconductor die or an electronic integrated circuit (EIC) die. In some arrangements, the electronic component 40 may include a modulator driver (DRV), a trans-impedance amplifier (TIA), and/or other active or passive elements. In some arrangements, the electronic component 40 is configured to modulate optical signals (e.g., light) in the photonic component 50. In some arrangements, the electrical component 40 includes a through silicon via (TSV) (not shown).

The photonic component 50 has a first surface 50a, a second surface 50b opposite to the first surface 50a, and an edge 50e (also referred to as a lateral surface) connecting the first surface 50a and the second surface 50b. In some arrangements, the first surface 50a of the photonic component 50 is an active surface. In some arrangements, the second surface 50b of the photonic component 50 is an inactive surface. The photonic component 50 includes an overhang 50h extending beyond the edge 10e of the carrier 10 along an axis perpendicular to one or more of the surfaces 50a, 50b, 10a, or 10b. The overhang 50h of the photonic component is configured to accommodate or attach an optical component 60. The overhang 50h may be shaped and sized to attach the optical component 60, such as a laser diode or an FAU by a pick-and-place process. In some arrangements, the photonic component 50 may be or include a photonic die, and may also be referred to as a semiconductor die, a photonic semiconductor die or a photonic integrated circuit (PIC) die. In some arrangements, the photonic component 50 may include a laser, a receiver, a waveguide, a photodetector, a semiconductor optical amplifiers (SOA), a grating coupler, a fiber coupling structure, an optical modulator (e.g., Mach-Zehnder modulator or microring modulator), and/or other active or passive elements.

With reference to FIG. 2, the processing component 20 is disposed on or adjacent to the first surface 10a of the carrier 10, and the I/O component 30 is disposed on or adjacent to the second surface 10b of the carrier. That is, the processing component 20 and the I/O component 30 are disposed on the opposite sides of the carrier 10. The processing component 20 and the I/O component 30 are physically separated or spaced apart from each other by the carrier 10. In some arrangements, the processing component 20 is electrically connected to the I/O component 30 through the carrier 10. The photonic component 50 is disposed on the second surface 10b of the carrier, and adjacent to the I/O component 30.

In some arrangements, at least a portion of the electronic component 40 may be embedded in the carrier 10, so that a thickness of the optoelectronic package 2 can be reduced. In some arrangements, the first surface 40a of the electronic component 40 may be exposed from the second surface 10b of the carrier 10. The carrier 10 may include a cavity 102 sized and shaped to accommodate the electronic component 40. The electronic component 40 may be disposed in the cavity 102 of the carrier 10. In some arrangements, the electronic component 40 is attached to the carrier 10 by an adhesive layer disposed on the second surface 40b of the electronic component 40 (not shown). In some arrangements, the adhesive layer may be or include a die attach film (DAF). In some arrangements, the adhesive layer may include a thermal interface material (TIM). In some arrangements, a filling material fills in a space between the electronic component 40 and an inner wall of the cavity 102 of the carrier 10 (not shown). In some arrangements, the filling material includes an underfill material. In some arrangements, the filling material includes an epoxy resin, a molding compound (e.g., an epoxy molding compound or other molding compound), polyimide, a phenolic compound or material, or a combination thereof.

The electronic component 40 bridges the I/O component 30 and the photonic component 50. Therefore, the I/O component 30 may be electrically connected to the photonic component 50 through the electronic component 40. The first surface 40a of the electronic component 40 may face the first surface 30a of the I/O component 30 and the first surface 50a of the photonic component 50. The electronic component 40 may cover or overlap with a portion of the I/O component 30 and a portion of the photonic component 50 along or parallel to an axis perpendicular to one or more of the surfaces 30a, 40a, or 50a. In some arrangements, the edge 40e1 of the electronic component 40 is located directly above the I/O component 30 along or parallel to an axis perpendicular to one or more of the surfaces 30a, 40a, or 50a. The edge 40e2 of the electronic component 40 (which is opposite to the edge 40e1) is located directly above the photonic component 50 along or parallel to an axis perpendicular to one or more of the surfaces 30a, 40a, or 50a. The edge 30e of the I/O component 30 and the edge 50e of the photonic component 50 face each other and are located directly below the electronic component 40 along or parallel to an axis perpendicular to one or more of the surfaces 30a, 40a, or 50a. In some arrangements, the electronic component 40 may extend beyond the edge 30e of the I/O component 30 along or parallel to an axis parallel to one or more of the surfaces 30a, 40a, or 50a. In some arrangements, the I/O component 30 may extend beyond the edge 40e1 of the electronic die 40 along or parallel to an axis parallel to one or more of the surfaces 30a, 40a, or 50a. In some arrangements. In some arrangements, the electronic component 40 may extend beyond the edge 50e of the photonic component 50 along or parallel to an axis parallel to one or more of the surfaces 30a, 40a, or 50a. In some arrangements, the photonic component 50 may extend beyond the edge 40e2 of the electronic die 40 along or parallel to an axis parallel to one or more of the surfaces 30a, 40a, or 50a.

The electronic component 40 may be electrically connected with the I/O component 30. In some arrangements, the first surface 40a of the electronic component 40 is electrically connected to the first surface 30a of the I/O component 30. In some arrangements, the electronic component 40 is electrically connected to the carrier 10 via the I/O component 30. The electronic component 40 may be electrically connected to the photonic component 50. In some arrangements, the first surface 40a of the electronic component 40 is electrically connected to the first surface 50a of the photonic component 50. The electronic component 40 and the photonic component 50 may function as a photonic engine. In some arrangements, the photonic component 50 is electrically connected with the I/O component 30 via the electronic component 40.

In some arrangements, the processing component 20 may be electrically connected to the photonic component 50 through the carrier 10, the I/O component 30 and the electronic component 40.

The I/O component 30 and the photonic component 50 are disposed on or adjacent to the second surface 10b of the carrier. In some arrangements, the photonic component 50 is physically separated or spaced apart from the carrier 10, for example, with a gap therebetween. In some arrangements, the I/O component 30 is physically separated or spaced apart from the carrier 10, for example, with a gap therebetween. In some arrangements, the I/O component 30 and the photonic component 50 are physically separated or spaced apart from each other, for example, with a gap therebetween. The first surface 30a of the I/O component 30 faces the second surface 10b of the carrier 10. The first surface 50a of the photonic component 50 faces the second surface 10b of the carrier 10.

In some arrangements, the photonic component 50 and the processing component 20 are disposed on opposite sides of the carrier 10. For example, the processing component 20 is disposed on the first surface 10a of the carrier 10, while the photonic component 50 is disposed on the second surface 10b of the carrier 10. Furthermore, the electronic component 40 is disposed away from the first surface 10a of the carrier 10 and spaced apart from the processing component 20. Therefore, the impact of heat generated by the processing component 20 during operation on the performance of the photonic component 50 or the electronic component 40 or a photonic engine including the photonic component 50 and the electronic component 40 can be alleviated.

The optoelectronic package 2 may further include conductors 206 between the processing component 20 and the carrier 10. The conductors 206 electrically connect or couple the processing component 20 to the carrier 10. The optoelectronic package 2 may further include conductors 106 between the carrier 10 and the I/O component 30. The conductors 106 electrically connect or couple the carrier 10 to the I/O component 30. The optoelectronic package 2 may further include conductors 406 between the electronic component 40 and the I/O component 30. The conductors 406 electrically connect or couple the electronic component 40 to the I/O component 30. The optoelectronic package 2 may further include conductors 408 between the electronic component 40 and the photonic component 50. The conductors 408 electrically connect or couple the electronic component 40 to the photonic component 50. In some arrangements, an electrically conductive path or a signal transmission path between the processing component 20 and the photonic component 50 passes through the RDL 204, the conductors 206, the carrier 10, the conductors 106, the I/O component 30, the conductors 406, the electronic component 40 and the conductors 408. In some arrangements, the conductors 106, 206, 406, 408 may include an electrically conductive material, such as a metallic material. In some arrangements, the conductors 106, 206, 406, 408 may include a solder material. In some arrangements, the conductors 106, 206, 406, 408 may be or include solder bumps or balls, conductive pillars, conductive studs, conductive pads, or so on.

The conductors 106 and the conductors 406 may be disposed on the I/O component 30. The conductor 106 has a size or dimension 106d (e.g., a width or a diameter). The conductor 406 has a size or dimension 406d (e.g., a width or a diameter). In some arrangements, the size or dimension 106d of the conductor 106 is different from the size or dimension 406d of the conductor 406. In some arrangements, the size or dimension 106d of the conductors 106 is larger than the size or dimension 406d of the conductor 406 as shown in FIG. 2 (for example, the conductors 406 may have a diameter in a range of 50 to 60 μm and the conductors 106 may have a diameter greater than 60 μm). In some arrangements, a pitch of the conductor 106d is different from a pitch of the conductor 406. The term “pitch” may refer to a center-to-center distance between adjacent conductive elements. Due to the conductors 406 and 106 may be made with different sizes, the electronic component 40 can be electrically coupled to the carrier 10. As a result, the issue of size difference between the conductive traces and pads of the electronic component 40 and the conductive traces and pads of the carrier 10 can be solved. Thus, in some arrangements, there is no RDL configured to electrically connect the carrier 10 with the electronic component 40. On the other hand, in some arrangements, the electronic component 40 can be electrically coupled to the photonic component 50 directly using the conductors 408 and there is no RDL between the electronic component 40 and the photonic component 50. In some arrangements, the conductors 408 may have a size or dimension similar to or substantially the same as a size or dimension of the conductors 406.

In some other arrangements, the optoelectronic package 2 may include one or more RDLs (not shown in FIG. 2) configured to electrically connect the carrier 10 to the electronic component 40 or one or more RDLs (not shown in FIG. 2) configured to electrically connect the electronic component 40 to the photonic component 50. In some arrangements, the RDL may be formed on the first surface 40a of the electronic component 40 and the second surface 10b of the carrier 10. In such arrangements, the conductors 106 may have a size or dimension 106d substantially the same as or similar to a size or dimension 406d of the conductors 406.

The optoelectronic package 2 may further include an optical component 60. The optical component 60 is disposed on and attached to the first surface 50a of the photonic component 50. The optical component 60 is optically coupled to the photonic component 50. In some arrangements, the optical component 60 includes one or more optical fibers. In some arrangements, the optical component 60 may be or include an FAU. In some arrangements, the optical component 60 may include an optical fiber (or fiber array unit) surrounded by a housing.

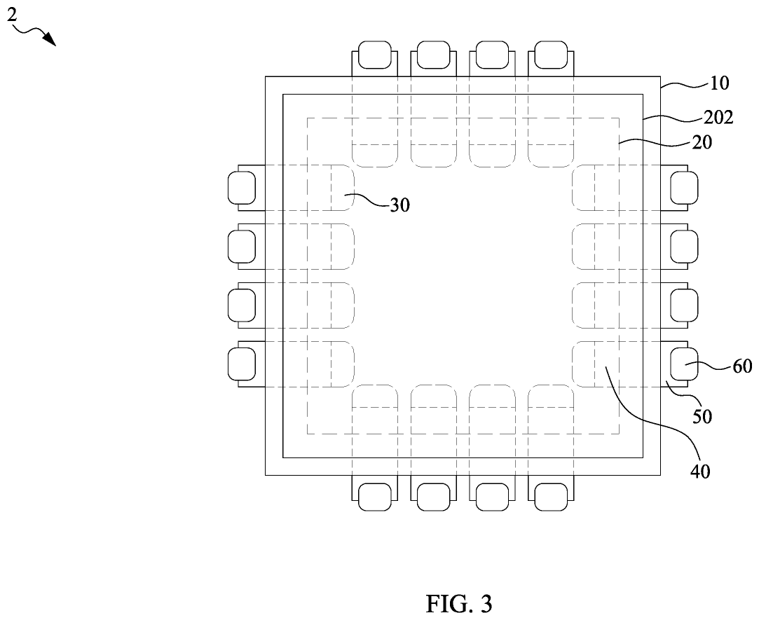

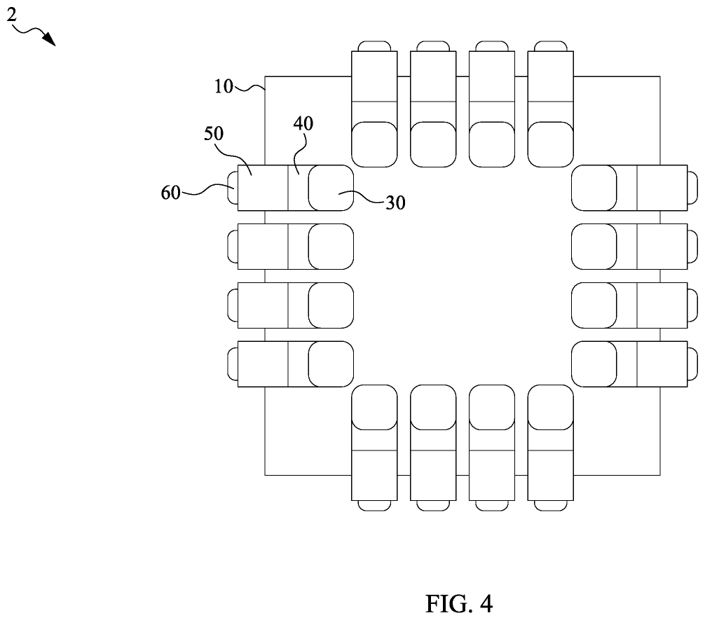

FIG. 3 illustrates a schematic top view of the optoelectronic package 2 of FIG. 2 in accordance with some arrangements of the present disclosure. The schematic top view of FIG. 3 shows a projection view of the components of the optoelectronic package 2 onto a horizontal plane (e.g., a plane parallel to a top surface 10a of the carrier 10). The outline of the portion of a component covered by obstructing component(s) is represented by a dash line. FIG. 4 illustrates a schematic bottom view of the optoelectronic package 2 of FIG. 2 in accordance with some arrangements of the present disclosure. As shown in FIG. 3 and FIG. 4, an I/O component 30, an electronic component 40, and a photonic component 50 may form an assembly. Multiple assemblies may be disposed around a periphery of the carrier 10, but are not limited thereto. In some arrangements, while in FIGS. 3 and 4, the assemblies are disposed around all four edges of the carrier 10, the assemblies may be disposed around one, or two or more edges of the carrier 10. The number of the assemblies shown in FIG. 3 and FIG. 4 is merely for illustration and can be adjusted as needed. With reference to the top projection view of FIG. 3, the processing component 20 covers or overlaps the I/O component 30, the electronic component 40, and the photonic component 50. In some arrangements, the processing component 20 overlaps with a portion of the electronic component 40 and a portion of the photonic component 50. As compared to the optoelectronic component 1 in accordance with some comparative arrangements of FIG. 1, the optoelectronic package 2 illustrated in FIGS. 2-4 occupies less surface area of the carrier 10 due to the 3D arrangement or packaging of the processing component 20, the electronic component 40, the I/O component 30, and the photonic component 50.

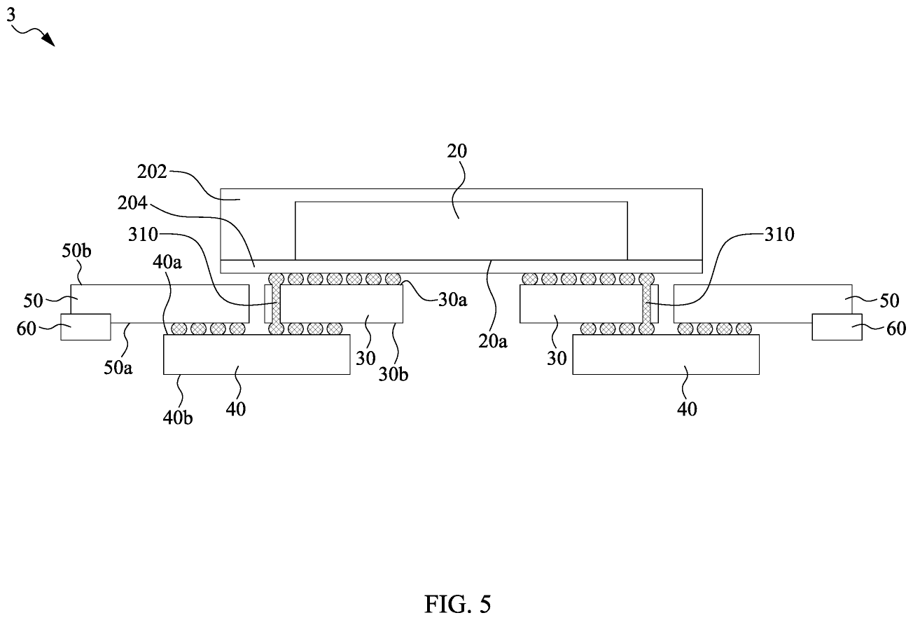

FIG. 5 illustrates a schematic cross-sectional view of an optoelectronic package 3 in accordance with some arrangements of the present disclosure. The optoelectronic package 3 is similar to the optoelectronic package 2 as described and illustrated with reference to FIG. 2, with the carrier 10 omitted. The processing component 20 may be electrically connected to the I/O component 30 through the RDL 204 and conductors between the processing component 20 and the I/O component 30, and therefore, a thickness of the optoelectronic package 3 may be decreased as compared to the optoelectronic package 2 which includes the carrier 10. The active surface 20a of the processing component 20 faces the first surface 30a (e.g. active surface) of the I/O component 30. The electronic component 40 is disposed on or adjacent to the second surface 30b (e.g., inactive surface) of the I/O component 30. The first surface 40a (e.g., active surface) of the electronic component 40 faces the second surface 30b (e.g., inactive surface) of the I/O component 30. The electronic component 40 may be electrically connected to the I/O component 30. In some arrangements, the I/O component 30 includes a conducive through via 310, such as TSV, extending from the first surface 30a to the second surface 30b through the I/O component 30. The electronic component 40 may be electrically connected to the I/O component 30 through the conductive through via 310. The I/O component 30 covers or overlaps with a portion of the first surface 40a of the electronic component 40 and exposes another portion of the first surface 40a of the electronic component 40. The photonic component 50 is disposed on a portion of the first surface 40a of the electronic component 40 exposed from the I/O component 30. The first surface 50a (e.g. active surface) of the photonic component 50 faces the first surface 40a (e.g. active surface) of the electronic component 40. The photonic component 50 may be electrically connected with the electronic component 40. In some arrangements, an electrically conductive path or a signal transmission path between the processing component 20 and the photonic component 50 passes through the RDL 204, the I/O component 30 (including the conductive through via 310), and the electronic component 40.

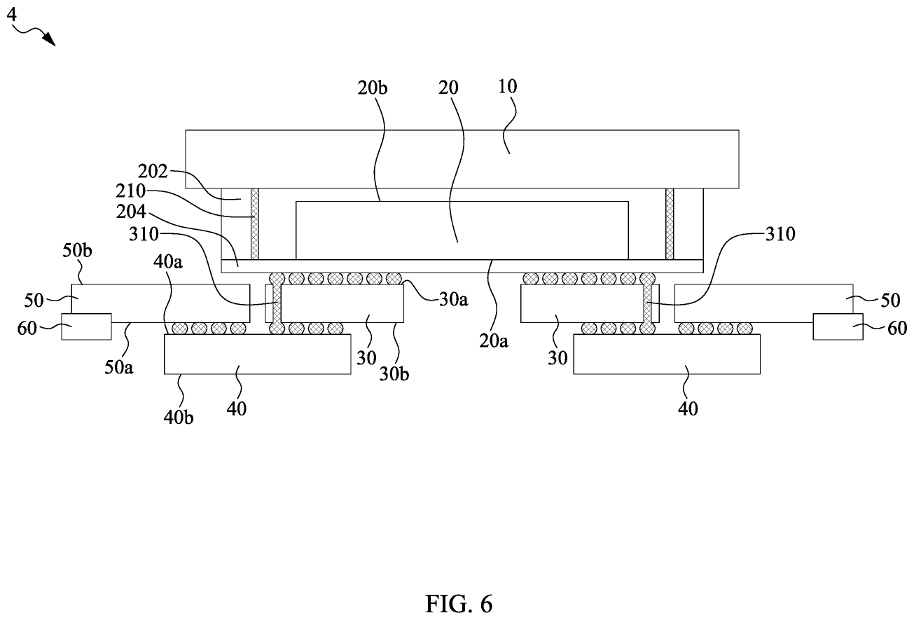

FIG. 6 illustrates a schematic cross-sectional view of an optoelectronic package 4 in accordance with some arrangements of the present disclosure. The optoelectronic package 4 is similar to the optoelectronic package 3 as described and illustrated with reference to FIG. 5, but includes a carrier 10 disposed over the processing component 20. As illustrated in FIG. 6, the carrier 10 is disposed over the surface 20b of the processing component 20. The surface 20b of the processing component 20 is opposite to the surface 20a (e.g., active surface) and may be an inactive surface. The optoelectronic package 4 further includes a conductive through via 210, such as a through molding via (TMV), extending through the encapsulant 202. The processing component 20 may be electrically connected to the carrier 10 through the RDL 204 and the conductive through via 210.

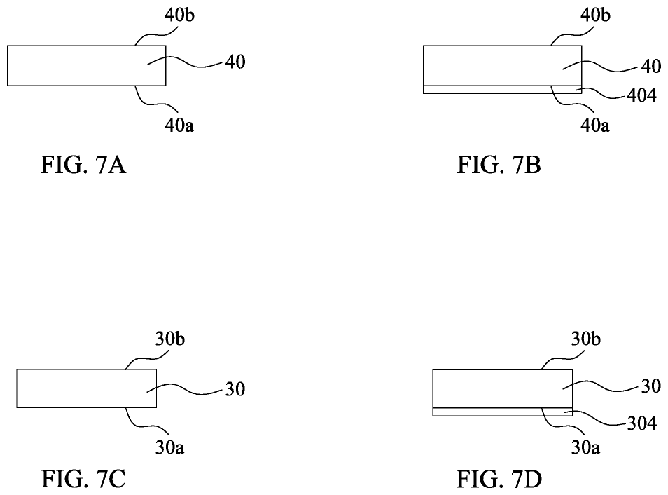

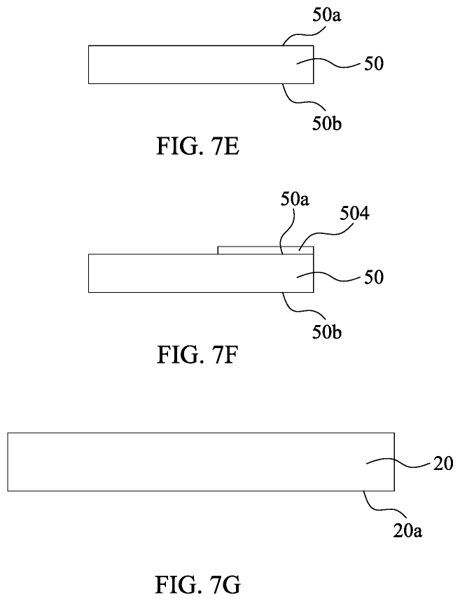

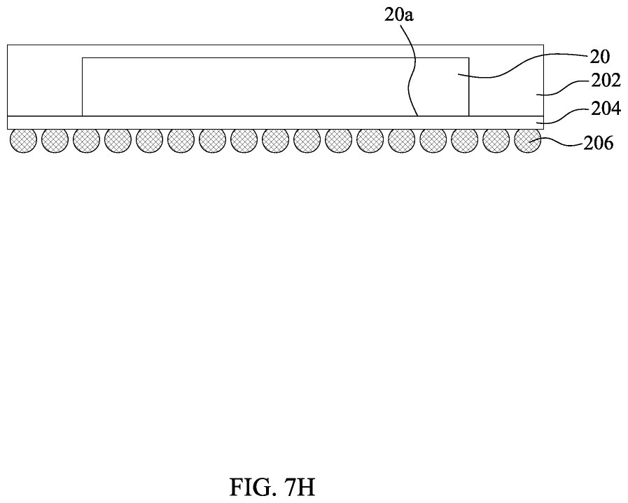

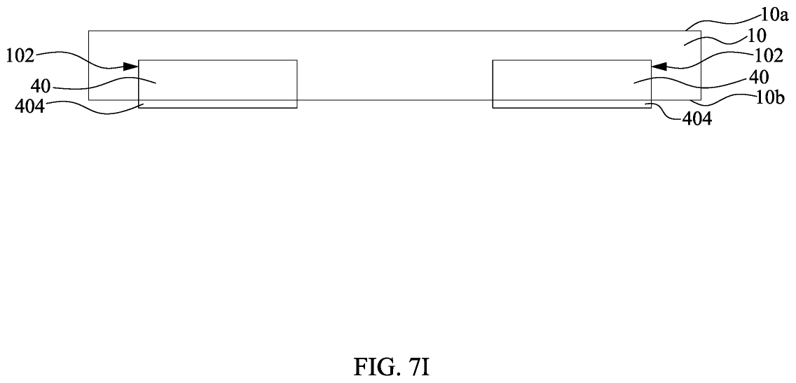

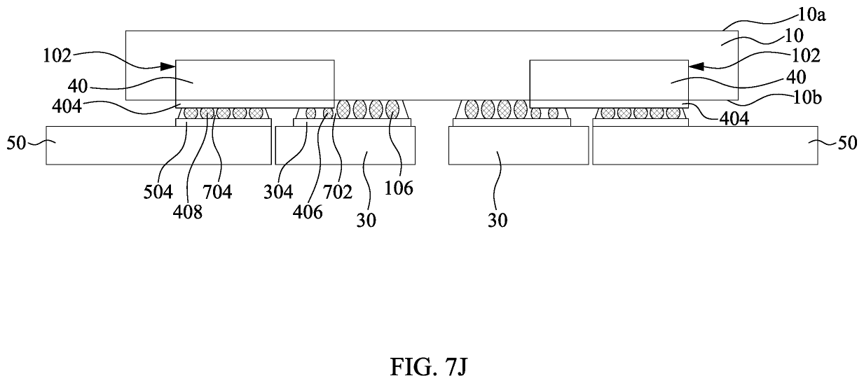

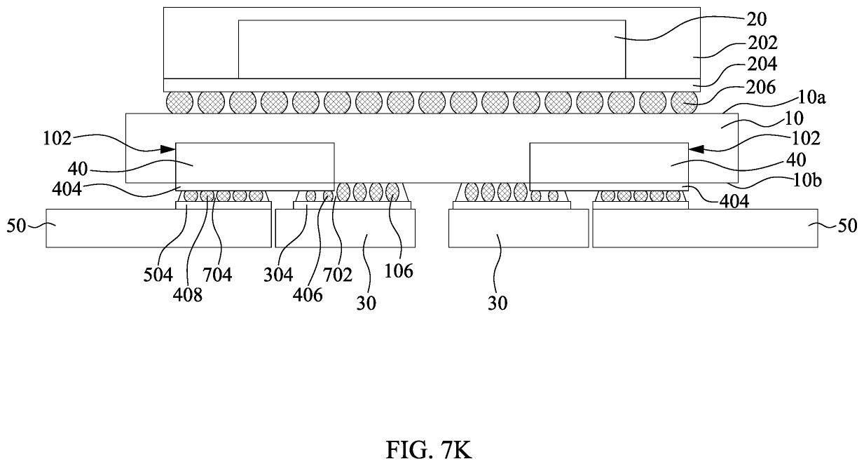

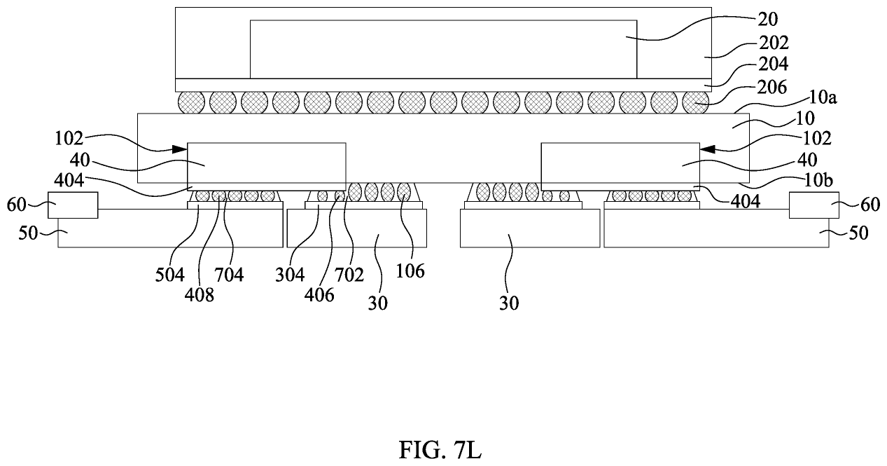

FIG. 7A, FIG. 7B, FIG. 7C, FIG. 7D, FIG. 7E, FIG. 7F, FIG. 7G, FIG. 7H, FIG. 7I, FIG. 7J, FIG. 7K and FIG. 7L illustrate various stages of a method for manufacturing an optoelectronic package in accordance with some arrangements of the present disclosure.

With reference to FIG. 7A, an electronic component 40 is provided. The electronic component 40 has a first surface 40a and a second surface 40b opposite to the first surface 40a. The first surface 40a of the electronic component 40 is an active surface.

With reference to FIG. 7B, an RDL 404 is optionally formed on the first surface 40a of the electronic component 40. In some arrangements, the RDL 404 include a dielectric layer and a conductive layer (including a conductive trace and a conductive via) embedded in the dielectric layer. In some arrangements, the RDL 404 may be, but is not limited to, a multi-layered RDL including conductive layers and dielectric layers stacked alternately. In some arrangements, the RDL 404 may include UBM.

With reference to FIG. 7C, an I/O component 30 is provided. The I/O component 30 has a first surface 30a and a second surface 30b opposite to the first surface 30a. The first surface 30a of the I/O component 30 is an active surface.

With reference to FIG. 7D, an RDL 304 is optionally formed on the first surface 30a of the I/O component 30. In some arrangements, the RDL 304 include a dielectric layer and a conductive layer (including a conductive trace and a conductive via) embedded in the dielectric layer. In some arrangements, the RDL 304 may be, but is not limited to, a multi-layered RDL including conductive layers and dielectric layers stacked alternately. In some arrangements, the RDL 304 may include UBM.

With reference to FIG. 7E, a photonic component 50 is provided. The photonic component 50 has a first surface 50a and a second surface 50b opposite to the first surface 50a. The first surface 50a of the photonic component 50 is an active surface.

With reference to FIG. 7F, an RDL 504 is optionally formed on the first surface 50a of the photonic component 50. The RDL 504 covers a portion of the active surface 50a of the photonic component 50 and exposes another portion of the active surface 50a of the photonic component 50. In some arrangements, the RDL 504 include a dielectric layer and a conductive layer (including a conductive trace and a conductive via) embedded in the dielectric layer. In some arrangements, the RDL 504 may be, but is not limited to, a multi-layered RDL including conductive layers and dielectric layers stacked alternately. In some arrangements, the RDL 504 may include UBM.

With reference to FIG. 7G, a processing component 20 is provided. The processing component 20 has an active surface 20a.

With reference to FIG. 7H, the processing component 20 is encapsulated by an encapsulant 202. The encapsulant 202 exposes the active surface 20a of the processing component 20. An RDL 204 is formed on the active surface 20a of the processing component 20 and the encapsulant 202. A plurality of conductors (e.g., solder bumps or balls) 206 are formed on the RDL 204.

With reference to FIG. 7I, a carrier 10 including a cavity 102 is provided. The carrier 10 has a first surface (e.g., a top surface) 10a and a second surface (e.g., a bottom surface) 10b opposite to the first surface 10a. The cavity 102 may be formed by removing a portion of the carrier 10 from the second surface 10b. The electronic component 40 is disposed in the cavity 102 of the carrier 10 and attached to the carrier 10.

With reference to FIG. 7J, the I/O component 30 and the photonic component 50 are disposed on the second surface 10b of the carrier 10. The photonic component 50 is disposed adjacent to the I/O component 30. The I/O component 30 is electrically with the carrier 10 and the electronic component 40 through conductors 106 and conductors 406, respectively. The photonic component 50 is electrically with the electronic component 40 through conductors 408. In some arrangements, a filling structure 702 (e.g., an underfill) is formed between the I/O component 30 and the carrier 10 and between the I/O component 30 and the electronic component 40 to surround and embed the conductors 106 and the conductors 406. In some arrangements, a filling structure 704 (e.g., an underfill) is formed between the photonic component 50 and the electronic component 40 to surround and embed the conductors 408.

With reference to FIG. 7K, the structure illustrated on FIG. 5H is disposed on and attached to the first surface 10a of the carrier 10 by, for example, a flip-chip process and/or a underfill process. The processing component 20 is electrically connected with the carrier 10 through conductors 206. In some arrangements, a filling structure (e.g., an underfill; not shown) may be formed between the carrier 10 and the RDL 204 to surround and embed the conductors 206.

With reference to FIG. 7L, an optical component 60 is disposed on the active surface 50a of the photonic component 50. A trench, such as a V-groove, a U-groove or so on, may be formed on the photonic component 50, and the optical component 60 is disposed in and attached to the trench of the photonic component 50. The optical component 60 is optically coupled to the photonic component 50.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of the arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially parallel” can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially perpendicular” can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. In addition, a first surface of an object is “substantially level” with a second surface of another object if the first surface and the second surface are at the same plane within a variation of ±10%, such as ±5%, ±4%, ±3%, ±2%, ±1%, ±0.5%, ±0.1% or ±0.05%, of a height/length of the object.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

While the present disclosure has been described and illustrated with reference to specific arrangements thereof, these descriptions and illustrations are not limiting. It should be understood by those skilled in the art that various changes may be made, and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An optoelectronic package, comprising:
an input/output (I/O) component;
a photonic component; and
an electronic component configured to modulate optical signals in the photonic component,
wherein the I/O component is electrically connected to the photonic component via the electronic component.

2. The optoelectronic package of claim 1, wherein the electronic component covers a portion of the I/O component and a portion the photonic component.

3. The optoelectronic package of claim 2, wherein an active surface of the electronic component faces an active surface of the I/O component.

4. The optoelectronic package of claim 2, wherein an active surface of the electronic component faces an active surface of the photonic component.

5. The optoelectronic package of claim 1, further comprising a processing component electrically connected to the I/O component, wherein the processing component and the I/O component are physically separated from each other.

6. The optoelectronic package of claim 5, wherein the electronic component is disposed over the I/O component, and the processing component is disposed over the electronic component.

7. The optoelectronic package of claim 1, wherein the photonic component is physically separated from the I/O component.

8. The optoelectronic package of claim 1, wherein the electronic component is embedded in a carrier.

9. The optoelectronic package of claim 8, wherein an active surface of the electronic component is exposed from the carrier and faces the I/O component and the photonic component.

10. The optoelectronic package of claim 8, wherein the photonic component comprises an overhang extending beyond an edge of the carrier.

11. An optoelectronic package, comprising:
a carrier;
a processing component disposed at a first side of the carrier; and
an I/O component disposed at a second side of the carrier, wherein the second side is opposite to the first side.

12. The optoelectronic package of claim 11, wherein the processing component is electrically connected to the I/O component via the carrier.

13. The optoelectronic package of claim 11, further comprising an electronic component disposed between the processing component and the I/O component.

14. The optoelectronic package of claim 13, wherein the electronic component is embedded in the carrier, and wherein an active surface of the electronic component is exposed from the second surface of the carrier.

15. The optoelectronic package of claim 13, further comprising a photonic component electrically connected to the I/O component via the electronic component.

16. The optoelectronic package of claim 15, wherein the photonic component comprises an overhang extending beyond an edge of the carrier.

17. An optoelectronic package, comprising:
a carrier;
an electronic component embedded in the carrier; and
an I/O component outside the carrier,
wherein the I/O component is electrically connected to the electronic component.

18. The optoelectronic package of claim 17, wherein the I/O component is electrically connected to the carrier.

19. The optoelectronic package of claim 17, further comprising a processing component disposed on the carrier, wherein the processing component and the I/O component are disposed on two opposite sides of the carrier.

20. The optoelectronic package of claim 19, wherein the processing component is electrically connected to the I/O component via the carrier.
